(19) United States
(12) Patent Application Publication
(10) Pub. No.: US 2026/0058548 A1
(43) Pub. Date: Feb. 26, 2026

(54) VOLTAGE REGULATOR MODULE

(71) Applicant: Delta Electronics, Inc., Taoyuan City (TW)

(72) Inventors: Yanbing Xia, Shanghai (CN); Dong Guo, Shanghai (CN); Guansong Cui, Shanghai (CN)

(21) Appl. No.: 19/286,175

(22) Filed: Jul. 30, 2025

(30) Foreign Application Priority Data
Aug. 20, 2024 (CN) 202411146746.3

(51) Int. Cl. H02M 3/00; H01F 27/24; H01F 27/28; H05K 1/18

(52) U.S. Cl. CPC H02M 3/003; H01F 27/24; H01F 27/28; H05K 1/181

(57) ABSTRACT

The present disclosure provides a voltage regulator module. The voltage regulator module includes a power element, a passive component, an inductor module and a conductor. The inductor module includes a magnetic core, and the magnetic core includes a concave structure. When the magnetic core is connected and attached to the second surface of a first printed circuit board, the passive component disposed on the second surface of the first printed circuit board is accommodated within the concave structure. The conductor is disposed on the magnetic core and configured to transmit electric power and electric signals. In this way, the size of the voltage regulator module is reduced, and the power density is enhanced.

### CROSS-REFERENCE TO RELATED APPLICATIONS

This application claims priority to China Patent Application No. 202411146746.3 filed on Aug. 20, 2024. The entire contents of the above-mentioned patent application are incorporated herein by reference for all purposes.

### FIELD OF THE INVENTION

The present disclosure relates to a power electronic field, and more particularly to a voltage regulator module.

### BACKGROUND OF THE INVENTION

A voltage regulator module (VRM) is configured to convert the output voltage from an upstream power supply unit (e.g., 12V) into the voltage required for the downstream processor. Recently, as the performance of the processor has continuously improved, the requirements of the voltage regulator module have increasingly focused on high efficiency, high power density, fast dynamic response, higher output current, and support for more circuit components.

Generally, a multi-phase coupled buck topology has a larger equivalent steady-state output inductance and a smaller equivalent dynamic output inductance. That is, the use of the multi-phase coupled buck topology can achieve higher efficiency and fast dynamic response. Consequently, the multi-phase coupled buck topologies have been widely applied to the voltage regulator modules. Furthermore, most of the voltage regulator modules on the market today use two-phase coupled buck topologies. In this way, the purpose of obtaining high efficiency and fast dynamic response can be achieved. The conventional two-phase coupled buck topology is usually equipped with an inductor with two lateral legs. Since two DrMOS (Driver-MOSFET) devices are required, the equivalent dynamic output inductance is larger, and the electrical characteristics about the response speed and the output current are not satisfied. In addition, due to the uses of two DrMOS devices, more input capacitors and bootstrap capacitors are needed. As a result, the overall size of the product is increased, and the power density is greatly reduced.

Therefore, there is a need to provide an improved voltage regulator module in order to overcome the drawbacks of the conventional technologies.

### SUMMARY OF THE INVENTION

The present disclosure provides a voltage regulator module. A magnetic core of an inductor module of the voltage regulator module includes a concave structure. When the magnetic core is connected and attached to the second surface of a first printed circuit board, all passive components on the second surface of the first printed circuit board are accommodated within the concave structure. In this way, the size of the voltage regulator module is reduced, and the power density is enhanced.

In accordance with an aspect of the present disclosure, a voltage regulator module is provided. The voltage regulator module includes at least one power element, at least one passive component, a first printed circuit board, an inductor module and at least one conductor. The first printed circuit board includes a first surface and a second surface opposed to each other. The at least one power element is disposed on the first surface, and the at least one passive component is disposed on the second surface. The inductor module includes a magnetic core and at least one winding. The magnetic core includes a top surface, a bottom surface and a concave structure. The top surface and the bottom surface are opposed to each other, and the top surface is connected and attached to the second surface. The concave structure is concavely formed from the top surface toward the bottom surface, and the at least one passive component on the second surface is accommodated within the concave structure. The at least one winding is embedded in the magnetic core. A portion of the at least one winding is exposed outside the top surface and formed as at least one pin, and the at least one pin is electrically connected with the at least one power element through the second surface. The at least one conductor is disposed on the magnetic core and configured to transmit electric power and electric signals.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic circuit diagram illustrating the circuitry topology of a voltage regulator module according to an embodiment of the present disclosure;

FIG. 2 is a schematic view illustrating the voltage regulator module shown in FIG. 1;

FIG. 3 is a schematic exploded view illustrating the voltage regulator module shown in FIG. 2 and taken from a top viewpoint;

FIG. 4 is a schematic exploded view illustrating the voltage regulator module shown in FIG. 2 and taken from a bottom viewpoint;

FIG. 5 is a schematic perspective view illustrating the structure of an inductor module of the voltage regulator module shown in FIG. 3;

FIG. 6 is a schematic top view illustrating the inductor module shown in FIG. 5; and

FIG. 7 is a schematic bottom view illustrating the inductor module shown in FIG. 5.

### DETAILED DESCRIPTION OF THE EMBODIMENT

The present disclosure will now be described more specifically with reference to the following embodiments. It is noted that the following descriptions of the embodiments of the present disclosure are presented herein for purpose of illustration and description only. It is not intended to be exhaustive or to be limited to the precise from disclosed.

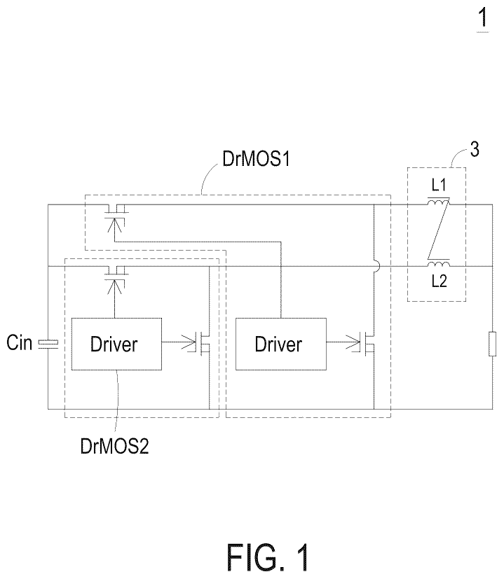

FIG. 1 is a schematic circuit diagram illustrating the circuitry topology of a voltage regulator module according to an embodiment of the present disclosure. The voltage regulator module 1 of the present disclosure can be applied to an electronic device. According to the output current requirements of the electronic devices, the voltage regulator module can be applied to single-phase or multi-phase boost conversion circuits, buck conversion circuits or buck-boost conversion circuits. The voltage regulator module 1 includes at least one power element, at least one passive component and at least one inductor module. For example, the voltage regulator module 1 shown in FIG. 1 is a two-phase buck conversion circuit. As shown in FIG. 1, the voltage regulator module 1 includes two power elements DrMOS1 and DrMOS2, one passive component (e.g., a capacitor Cin) and one inductor module (including two inductors L1 and L2). In this context, the term “DrMOS” is the integration of one driver and two MOSFET transistors. Each of the power elements DrMOS1 and the DrMOS2 includes two MOS switches and one driver for driving the two MOS switches. The example of the at least one passive component in the voltage regulator module 1 of the present disclosure can be varied according to the practical requirements. For example, in another embodiment, the at least one passive component includes capacitors, resistors, or any other appropriate passive components.

Please refer to FIG. 1 again. The node between the two MOS switches of the power element DrMOS1 is connected to the first terminal of the inductor L1, and thus the power element DrMOS1 and the inductor L1 are collaboratively formed as a first phase circuit of the two-phase buck conversion circuit. The node between the two MOS switches of the power element DrMOS2 is connected to the first terminal of the inductor L2, and thus the power element DrMOS2 and the inductor L2 are collaboratively formed as a second phase circuit of the two-phase buck conversion circuit. In other words, the voltage regulator module 1 includes the first phase circuit and the second phase circuit of the two-phase buck conversion circuit, and the voltage regulator module 1 includes two power elements (DrMOSs) and two inductors. It is noted that the number of the power elements and the number of the inductor may be varied. For example, in some embodiments, the number of the DrMOSs and the number of the inductors can be adjusted according to the magnitude of the output current. Furthermore, the inductors L1 and L2 are positively or negatively coupled to each other to improve the electrical characteristics. In the embodiment of FIG. 1, the two-phase buck conversion circuit is employed. In some embodiments, the two-phase buck conversion circuit can be combined with several other two-phase conversion circuits or multi-phase converter circuits to meet various practical requirements.

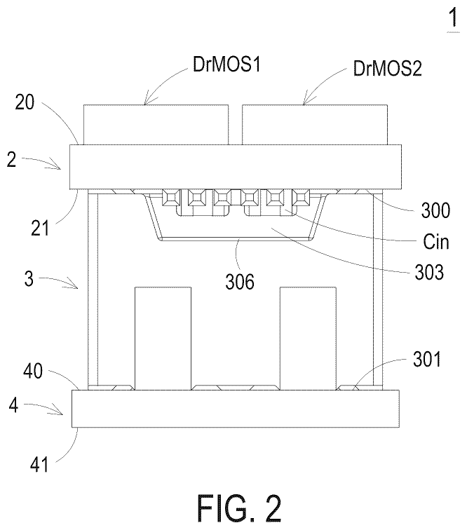

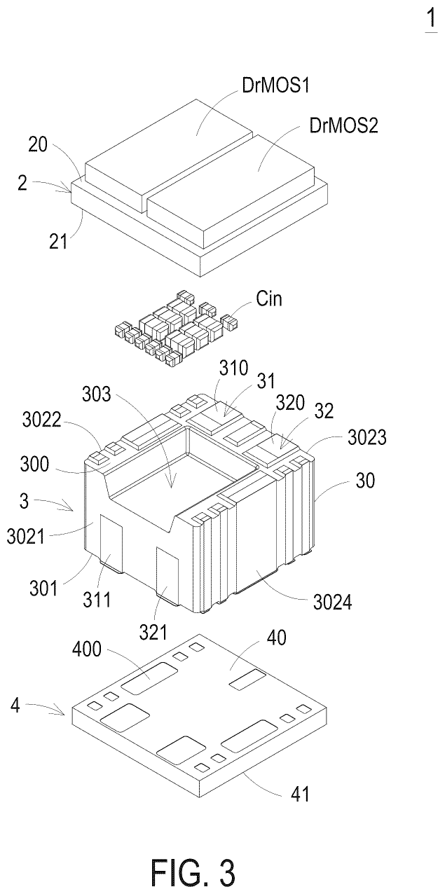

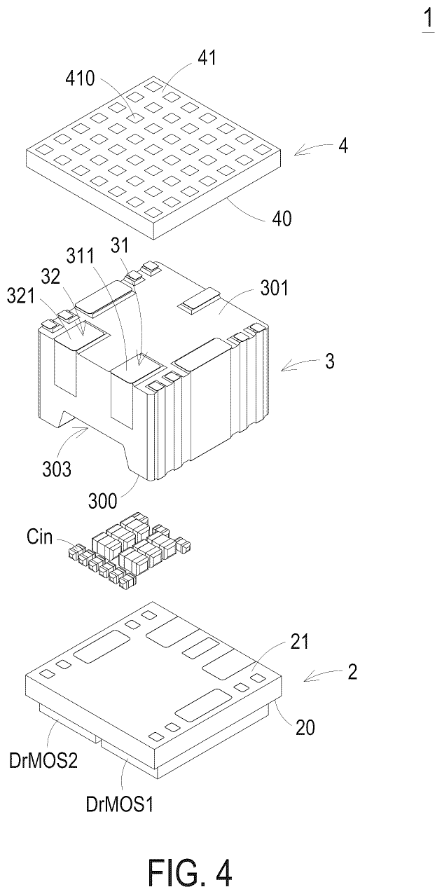

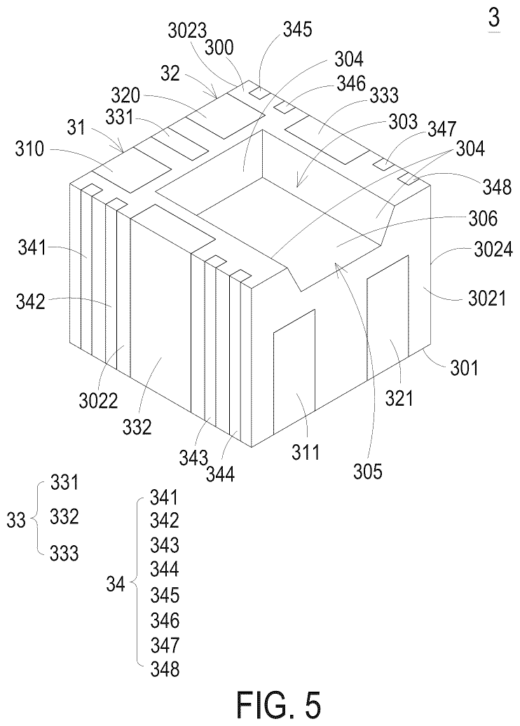

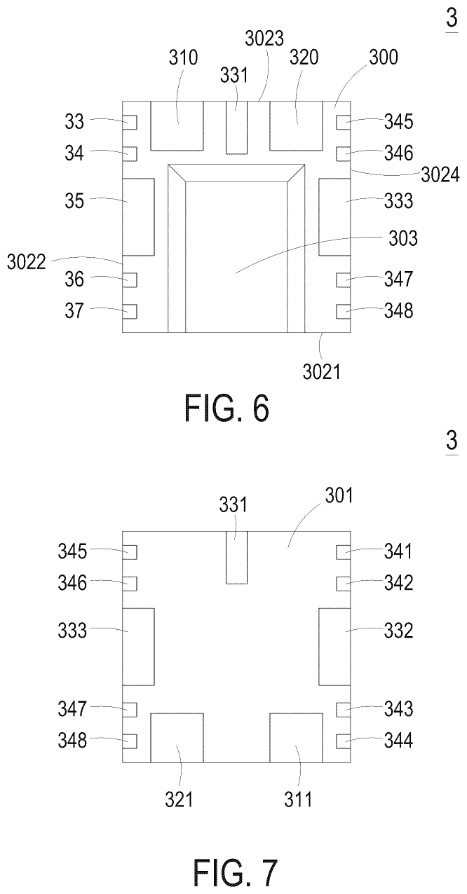

FIG. 2 is a schematic view illustrating the voltage regulator module shown in FIG. 1. FIG. 3 is a schematic exploded view illustrating the voltage regulator module shown in FIG. 2 and taken from a top viewpoint. FIG. 4 is a schematic exploded view illustrating the voltage regulator module shown in FIG. 2 and taken from a bottom viewpoint. FIG. 5 is a schematic perspective view illustrating the structure of an inductor module of the voltage regulator module shown in FIG. 3. FIG. 6 is a schematic top view illustrating the inductor module shown in FIG. 5. FIG. 7 is a schematic bottom view illustrating the inductor module shown in FIG. 5.

Please refer to FIGS. 2, 3, 4, 5, 6 and 7. For illustration, the voltage regulator module 1 is applied to the two-phase buck conversion circuit shown in FIG. 1. In an embodiment, the voltage regulator module 1 includes two power elements DrMOS1 and DrMOS2, one passive component (e.g., the capacitor Cin), a first printed circuit board 2 and an inductor module 3. The first printed circuit board 2 has a first surface 20 and a second surface 21 opposed to each other. As shown in FIG. 2, the two power elements DrMOS1 and DrMOS2 are disposed on the first surface 20 of the first printed circuit board 2. The passive component (e.g., the capacitor Cin) is disposed on the second surface 21 of the first printed circuit board 2. In some embodiments, the first printed circuit board 2 is a multilayer printed circuit board.

Please refer to FIGS. 2, 3, 4, 5, 6 and 7 again. The inductor module 3 includes a magnetic core 30 and at least one winding. The magnetic core 30 substantially has a rectangular cuboid structure. In addition, the magnetic core 30 includes a top surface 300, a bottom surface 301, four lateral surfaces 3021, 3022, 3023 and 3024 and a concave structure 303. The top surface 300 and the bottom surface 301 are opposed to each other. The four lateral surfaces 3021, 3022, 3023 and 3024 are arranged between the top surface 300 and the bottom surface 301. In addition, the top surface 300 of the magnetic core 30 is connected and attached to the second surface 21 of the first printed circuit board 2 in a soldering manner or any other appropriate connecting manner. The concave structure 303 is concavely formed from the top surface 300 toward the bottom surface 301. The space size of the concave structure 303 is large enough to accommodate all passive components (e.g., a plurality of capacitors Cin shown in FIGS. 2 to 7, resistors, or any other appropriate passive components) on the second surface 21 of the first printed circuit board 2.

In FIG. 1, only one capacitor Cin is shown. This capacitor Cin is used to represent the input capacitor of the two-phase buck conversion circuit. In some embodiments, the capacitor Cin represents the input capacitor, bypass capacitor, bootstrap capacitor, or other possible capacitor.

The concave structure 303 is defined by an inner wall 304, a notch 305 and a bottom wall 306. The inner wall 304, the notch 305 and the bottom wall 306 are connected with each other. The notch 305 is formed in the lateral wall 3021 of the magnetic core 30. The passive components accommodated within the concave structure 303 can be directly observed through the notch 305. Due to the arrangement of the notch 305, the subsequent procedure of welding the passive components will be simplified.

In an embodiment, the concave structure 303 has a trapezoid shape at the lateral wall 3021 of the magnetic core 30 where the notch 305 is formed. Due to the trapezoid shape, the concave structure 303 can be formed more easily, and the possibility of causing the cracking of the magnetic core 30 in response to the excessive pressure in the concave structure formation process will be minimized. It is noted that the shape of the notch 305 is not restricted. For example, in some embodiments, the notch 305 of the concave structure 303 has a rectangular shape, an arc shape, a triangular shape or any other appropriate shape.

After the top surface 300 of the magnetic core 30 and the second surface 21 of the first printed circuit board 2 are connected and attached to each other, all passive components on the second surface 21 of the first printed circuit board 2 are accommodated within the concave structure 303.

As shown in FIG. 2, the capacitors Cin on the second surface 21 of the first printed circuit board 2 are accommodated within the concave structure 303. In this way, the size of the voltage regulator module 1 is reduced, and the power density is enhanced. Furthermore, no passive components are disposed on the region of the second surface 21 of the first printed circuit board 2 corresponding to the region of the top surface 31 of the magnetic core 30 without the concave structure 303. Consequently, the region of the top surface 31 of the magnetic core 30 without the concave structure 303 is directly contacted with the second surface 21 of the first printed circuit board 2 or is indirectly contacted with the second surface 21 of the first printed circuit board 2 through pins of the winding of the inductor module 3 and at least one conductor.

In some embodiments, the depth of the concave structure 303 is greater than or equal to the height of the passive component that is accommodated within the concave structure 303 and is the tallest. Especially, the depth of the concave structure 303 is the distance between the second surface 21 of the first printed circuit board 2 and the bottom wall 306 of the magnetic core 30.

In some embodiments, the magnetic core 30 is formed by compressing magnetic material such as ferrite or magnetic powder core.

As shown in FIG. 5, the at least one winding includes a first winding 31 and a second winding 32. The first winding 31 and the second winding 32 are embedded into the magnetic core 30 in a compressing manner. In addition, two terminals of the first winding 31 are exposed outside the magnetic core 30 and respectively formed as a first pin 310 and a second pin 311, which are opposed to each other. Similarly, two terminals of the second winding 32 are exposed outside the magnetic core 30 and respectively formed as a third pin 320 and a fourth pin 321, which are opposed to each other. The first pin 310 and the second pin 320 are disposed on the lateral wall 3023 and the top surface 300 of the magnetic core 30. In addition, the first pin 310 and the third pin 320 are contacted with the second surface 21 of the first printed circuit board 2, and the first pin 310 and the third pin 320 are electrically connected with the power elements DrMOS1 and DrMOS2 on the first surface 20 of the first printed circuit board 2 through the first printed circuit board 2. The second pin 311 and the fourth pin 321 are disposed on the lateral wall 3021 and the bottom surface 301 of the magnetic core 30. The first winding 31 and the magnetic core 30 are collaboratively formed as the inductor L1 shown in FIG. 1. Similarly, the second winding 32 and the magnetic core 30 are collaboratively formed as the inductor L2 shown in FIG. 1.

Please refer to FIGS. 5, 6 and 7 again. The at least one conductor includes at least one first conductor 33 and at least one second conductor 34. The first conductor 33 and the second conductor 34 are C-shape metal sheets. Each of the conductors is disposed on the top surface 300, the bottom surface 301 and one of the lateral walls 3022, 3023 and 3024 of the magnetic core 30. Moreover, the arrangement of the first conductor 33 and the second conductor 34 can provide associated electrical connection paths for the voltage regulator module 1. For example, the voltage regulator module 1 can be electrically connected with a power source of the input voltage or the ground terminal through the at least one first conductor 33. In addition, the voltage regulator module 1 can be electrically connected to a signal terminal through the at least one second conductor 34.

In an embodiment, one of the at least one first conductor 33 is connected with a power supply terminal (not shown) and the driver of the power element (i.e., DrMOS). Consequently, electric power can be transmitted to the driver through the first conductor 33. In some embodiments, the first conductor 33 and the second conductor 34 are attached to the second surface 21 of the first printed circuit board 2 in a soldering manner, and thus the flatness of the soldering surface is enhanced.

In an embodiment, the first conductor 33 and the second conductor 34 are conductive posts (e.g., copper posts). In an embodiment, the at least one first conductor 33 includes a plurality of first conductors 331, 332 and 333. A portion of the first conductor 331 is disposed on the lateral wall 3023, a portion of the first conductor 332 is disposed on the lateral wall 3022, and a portion of the first conductor 333 is disposed on the lateral wall 3024. Similarly, the at least one second conductor 34 includes a plurality of second conductors 341, 342, 343, 344, 345, 346, 347 and 348. The second conductors 341, 342, 343 and 344 are disposed on the lateral wall 3022, and the second conductors 345, 346, 347 and 348 are disposed on the lateral wall 3024.

In some embodiments, the voltage regulator module 1 further includes a second printed circuit board 4. The second printed circuit board 4 includes a third surface 40 and a fourth surface 41 opposed to each other. The third surface 40 of the second printed circuit board 4 is connected and attached to the bottom surface 301 of the magnetic core 30 in a soldering manner, and thus the flatness of the soldering surface is enhanced. The input and output pins of the voltage regulator module 1 are led out to the fourth surface 41 of the second printed circuit board 4. Consequently, these pins can be connected with the downstream circuit (not shown) of the voltage regulator module 1 and an upstream system board (not shown). Please refer to FIGS. 3 and 4 again. In an embodiment, a plurality of first solder pads 400 are disposed on the third surface 40 of the second printed circuit board 4, and a plurality of second solder pads 410 are formed on the fourth surface 40 of the second printed circuit board 4. Each of the first solder pad 400 is electrically connected with one of the first conductor 33, the second conductor 34, the second pin 311 and the fourth pin 321. The plurality of second solder pads 410 are electrically connected with the downstream circuit of the voltage regulator module 1 and the upstream system board (not shown).

From the above descriptions, the present disclosure provides a voltage regulator module. The magnetic core of the inductor module of the voltage regulator module includes a concave structure. When the magnetic core is connected and attached to the second surface of the first printed circuit board, all passive components on the second surface of the first printed circuit board are accommodated within the concave structure. In this way, the size of the voltage regulator module is reduced, and the power density is enhanced.

It is to be understood that the disclosure needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A voltage regulator module, comprising:
at least one power element;
at least one passive component;
a first printed circuit board comprising a first surface and a second surface opposed to each other, wherein the at least one power element is disposed on the first surface, and the at least one passive component is disposed on the second surface;
an inductor module comprising a magnetic core and at least one winding, wherein the magnetic core comprises a top surface and a bottom surface opposed to each other, and the top surface is connected and attached to the second surface, wherein the magnetic core comprises a concave structure, the concave structure is concavely formed from the top surface toward the bottom surface, and the at least one passive component on the second surface is accommodated within the concave structure, wherein the at least one winding is embedded in the magnetic core, a portion of the at least one winding is exposed outside the top surface and formed as at least one pin, and the at least one pin is electrically connected with the at least one power element through the second surface; and
at least one conductor disposed on the magnetic core and configured to transmit electric power and electric signals.

2. The voltage regulator module according to claim 1, wherein the voltage regulator module further comprises a second printed circuit board, and the second printed circuit board comprises a third surface and a fourth surface opposed to each other, wherein the third surface is connected and attached to the bottom surface, and the at least one conductor is electrically connected to the first printed circuit board and the second printed circuit board.

3. The voltage regulator module according to claim 1, wherein the at least one power element comprises a plurality of power elements, and the at least one winding comprises a plurality of windings, wherein each of the plurality of windings comprises the two pins, and the two pins are respectively exposed outside the top surface and the bottom surface, wherein a number of the plurality of power elements and a number of the plurality of windings are equal, and the plurality of the power elements are electrically connected to the corresponding windings, respectively.

4. The voltage regulator module according to claim 1, wherein the at least one passive component comprises a plurality of passive components, and the plurality of passive components are disposed within the concave structure, wherein a region of the top surface without the concave structure is directly contacted with the second surface or indirectly contacted with the second surface through the at least one pin of the at least one winding and the at least one conductor.

5. The voltage regulator module according to claim 4, wherein a depth of the concave structure is deeper than or equal to a height of a tallest one of the plurality of passive components on the second surface.

6. The voltage regulator module according to claim 1, wherein each of the at least one conductor is a C-shape metal sheet, and the at least one conductor is disposed on the top surface, the bottom surface and at least one of a plurality of lateral walls of the magnetic core.

7. The voltage regulator module according to claim 6, wherein the concave structure comprises an inner wall, a notch and a bottom wall, and the notch is formed in the lateral wall of the magnetic core without the conductor.

8. The voltage regulator module according to claim 7, wherein the concave structure has a trapezoid shape at the lateral wall of the magnetic core where the notch is formed.

9. The voltage regulator module according to claim 1, wherein the at least one conductor comprises at least one first conductor and at least one second conductor, wherein the electric power is transmitted through the at least one first conductor, and the electric signals are transmitted through the at least one second conductor.

10. The voltage regulator module according to claim 9, wherein the at least one first conductor comprises a plurality of first conductors, and the at least one second conductor comprises a plurality of second conductors, wherein the voltage regulator module is electrically connected with a power source of an input voltage and a ground terminal through the at least one first conductor, and the voltage regulator module is connected with a signal terminal through the plurality of second conductors.

11. The voltage regulator module according to claim 10, wherein one of the at least one power element is a DrMOS device comprising two switches and a driver, wherein at least one of the plurality of first conductors is electrically connected to a supply power terminal and the driver to transmit electric power to the driver.

12. The voltage regulator module according to claim 1, wherein all of the passive components are disposed within the concave structure.

13. The voltage regulator module according to claim 12, wherein the passive components comprise capacitors and resistors.

14. The voltage regulator module according to claim 13, wherein the capacitors comprise an input capacitor, a bypass capacitor or a bootstrap capacitor.

15. The voltage regulator module according to claim 7, wherein the passive components disposed within the concave structure and the bottom wall are separated by air.
